(19) United States
(12) Patent Application Publication
(10) Pub. No.: US 2022/0007493 A1
(43) Pub. Date: Jan. 6, 2022

(54) HEAT DISSIPATION FROM ACTIVE DEVICES CONNECTED TO CONNECTORS

(71) Applicant: Reflex Photonics, Inc., Kirkland (CA)

(72) Inventor: David Robert Rolston, Beaconsfield (CA)

(21) Appl. No.: 17/290,592

(22) PCT Filed: Oct. 30, 2019
(86) PCT No.: PCT/CA2019/051533

§ 371 Date: Apr. 30, 2021

Related U.S. Application Data
(60) Provisional application No. 62/754,179, filed on Nov. 1, 2018.

(51) Int. Cl. H05K 1/02; H01R 12/72; G02B 6/42

(52) U.S. Cl. CPC H05K 1/0204; G02B 6/3897; G02B 6/4292; H01R 12/724

(57) ABSTRACT

An assembly comprising a connector board having a front side and a back side, a connector mounted to the connector board, the connector having a mating end extending outwardly from the front side of the connector board, and a heatsink extending outwardly from the back side of the connector board and aligned with the connector, the heatsink comprising a plurality of fins extending parallel to the connector board for drawing heat through the connector from the front side to the back side of the connector board.

### CROSS-REFERENCE TO RELATED APPLICATIONS

The present application is a national phase entry of International Application No. PCT/CA2019/051533 filed on Oct. 30, 2019, which claims priority to U.S. Provisional Patent Application No. 62/754,179 filed on Nov. 1, 2018, the contents of which are hereby incorporated herein by reference in their entirety.

### FIELD OF DISCLOSURE

The present disclosure is directed to a texture material dispensing system that includes a pivotable outlet having an adjustable orifice. The texture material dispensing system may be used for dispensing a texture material onto a target surface.

### BACKGROUND

A backplane is a board-like surface having multiple connectors, whereby the connectors are themselves linked to form a bus. The connectors receive expansion cards, expansion boards, adapter cards, accessory cards, or any other type of printed circuit board that can provide a desired functionality.

Backplanes are often preferred to cables because of their greater reliability. In a cabled system, repetitive flexing of the cables when a card is added or removed from the system may eventually lead to mechanical failure. Backplanes do not suffer from this drawback, and their life expectancy is mainly limited by the longevity of its connectors.

Backplanes are widely used in many types of computing systems. Therefore, improvements are needed to the board and connector assembly forming backplanes to increase the overall longevity of the computing system.

### BRIEF DESCRIPTION OF THE DISCLOSURE

In accordance with a broad aspect, there is provided an assembly. The assembly comprises a connector board having a front side and a back side, a connector mounted to the connector board, the connector having a mating end extending outwardly from the front side of the connector board, and a heatsink extending outwardly from the back side of the connector board and aligned with the connector, the heatsink comprising a plurality of fins extending parallel to the connector board for drawing heat through the connector from the front side to the back side of the connector board.

In some embodiments, the connector and the heatsink form an integral piece.

In some embodiments, the connector is embedded in the connector board and extends from the front side to the back side.

In some embodiments, the connector comprises at least one of an electrical cable, an optical cable, an electrical contact, and an optical contact.

In some embodiments, the connector is an optical connector. In some embodiments, the optical connector comprises an optical fiber cable extending outwardly from the back side of the connector board. In some embodiments, the optical fiber cable extends through the heatsink, underneath the plurality of fins.

In some embodiments, the plurality of fins comprise a matrix of at least two by two fins.

In some embodiments, the assembly further comprises a plurality of connectors mounted to the connector board and a plurality of heatsinks aligned with the plurality of connectors.

In some embodiments, the assembly further comprises a device board having a top surface and a bottom surface; and an active device mounted to the top surface of the device board and mated with the mating end of the connector. In some embodiments, the active device is an optical transceiver, and wherein the connector is an optical to electrical connector. In some embodiments, there is a thermal gap pad provided between the active device and the mating end of the connector.

In accordance with another broad aspect, there is provided a connector comprising a mating end configured for mating with an active device, and a back end opposite the mating end, the back end comprising a heatsink aligned with the mating end and having a plurality of fins extending vertically for releasing heat drawn through the mating end.

In accordance with yet another broad aspect, there is provided a method for dissipating heat generated by an active device on a device board. The method comprises mating the active device to a mating end of a connector mounted to a connector board, the mating end extending outwardly from a front side of the connector board, creating a thermal path through the connector to a back side of the connector board with a heatsink extending outwardly from the back side of the connector board and aligned with the connector, the heatsink comprising a plurality of fins extending parallel to the connector board, and drawing heat generated by the active device through the thermal path to release the heat at the back side of the connector board.

Features of the assemblies, connectors, and methods described herein may be used in various combinations, in accordance with the embodiments described herein.

### BRIEF DESCRIPTION OF THE DRAWINGS

Reference is now made to the accompanying figures in which:

FIG. 1 is a side view of a board and connector assembly, in accordance with an illustrative embodiment;

FIG. 2 is a side view of the assembly of FIG. 1 with an active device and board assembly, in accordance with an illustrative embodiment;

FIG. 3 is perspective view of the active device connected to the assembly of FIG. 1, in accordance with an illustrative embodiment;

FIG. 4 is a schematic illustration of the thermal path created through the assembly of FIG. 1, in accordance with an illustrative embodiment; and

FIG. 5 is side view of the assembly of FIG. 1 with multiple connectors on the board, in accordance with an illustrative embodiment.

It will be noted that throughout the appended drawings, like features are identified by like reference numerals.

### DETAILED DESCRIPTION

There is described herein an assembly for dissipating heat from an active device. The active device may be any type of circuit component with the ability to electrically control electron flow, such as but not limited to a transistor, a transceiver, a microchip, a silicon-controlled rectifier (SCR), a triac, and a vacuum tube. The active device may be a current-controlled device, a voltage-controlled device, or both. The active device may be a single active component or a plurality of components composed of one or more active components and one or more passive components. The active device may be packaged as a chip or a module, or unpackaged.

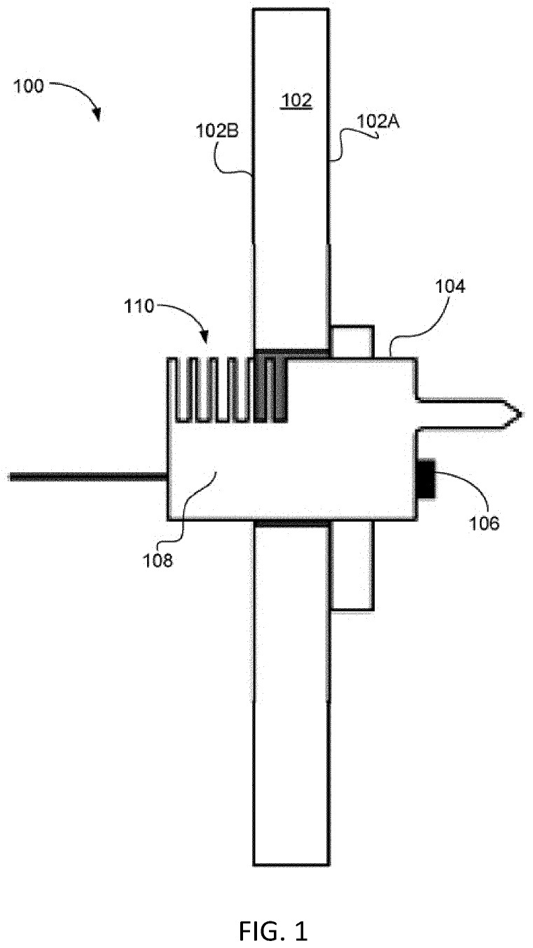

FIG. 1 illustrates an example embodiment of an assembly 100. A connector board 102 having a front side 102a and a back side 102b is assembled with a connector 104. The connector board 102 may be a printed circuit board or simply a substrate to act as a mechanical support for the connector 104. In some embodiments, the connector board 102 is a backplane. In some embodiments, the connector board 102 is a motherboard, a midplane, or a riser card. Other embodiments may also apply.

The connector 104 is mounted to the connector board 102. In some embodiments, the connector 104 is attached to the front side 102a of the connector board 102. In some embodiments, the connector 104 is embedded in the connector board 102 and extends between the front side 102a and the back side 102b. In some embodiments, the connector 104 is embedded in the connector board 102 and extends partially through the connector board 102 from the front side 102a towards the back side 102b. The connector 104 has a mating end 106 that extends outwardly from the front side 102a of the connector board 102, for mating with the active device. In some embodiments, the connector 104 is a floating connector designed to move slightly to account for misalignments. The connector 104 may be any type of electrical, optical, electro-optic, or opto-electric connector. In the case of an optical connector, the mating end may comprise a ferrule and/or a coupling mechanism. Materials for the connector 104 include but are not limited to aluminum, stainless steel, and plastic. Examples for the optical connector 104 include multi-terminal (MT) plastic and zirconia single-fiber ferrules as used in connector assemblies such as the single-connector (SC), and Lucent-Connector (LC).

A heatsink 108 extends outwardly from the back side 102b of the connector board 102. In some embodiments, the heatsink 108 is formed integrally with the connector 104 and forms the backend of the connector 104. In some embodiments, the heatsink 108 is separate from the connector 104 and is mounted to the connector board 102, either embedded therein or attached to the back side 102b. The heatsink 108 is aligned with the connector 104 to create a thermal path from the front side 102a to the backside 102b of the connector board 102. The heatsink 108 comprises a plurality of fins 110 that extend parallel to the connector board 102, either upwardly as illustrated or downwardly. The fins 110 may be composed of a single row of two or more fins. Alternatively, the fins 110 are composed of a matrix of at least 2×2 fins. For example, there may be 2×3 fins, 4×2 fins, 3×5 fins, etc. These numbers are for illustrative purposes only and other embodiments may apply. Examples of materials for the heatsink 108 include aluminum (anodized), nickel-plated zinc, and stainless steel.

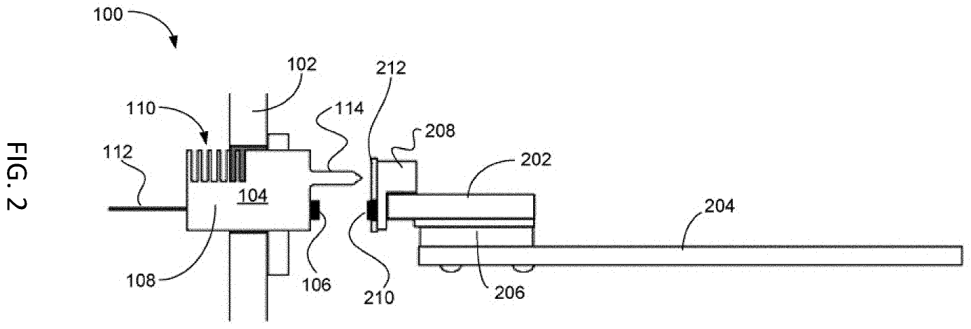

Referring now to FIG. 2, assembly 100 is configured for connecting to active device 202. The active device 202 is mounted to a device board 204, which may be an expansion card, an expansion board, an adapter card, an accessory card, a daughter card or any other type of printed circuit board. In some embodiments, the device board 204 is simply a substrate that acts as a mechanical support for the active device 202.

In some embodiments, the active device 202 is mounted to the device board 204 via a spacer or mounting block 206. Alternatively, the active device 202 is provided directly on the device board 204. The active device 202 may be mounted to the device board 204 via any suitable board mounting technology, such as but not limited to surface-mount technology and through-hole technology, using any suitable assembly techniques.

The active device comprises a coupling end 210 for mechanically coupling with the mating end 106 of the connector 104. The coupling end 210 and mating end 106 have complementary interfaces that are compatible with a given connector standard. Example standards for electrical connectors are EIA 364F, EIA264-1000, ISO/IEC TR 29106, and IEC 61586 TS. Example standards for optical connectors are VITA 42, VITA 57.x, VITA 74, and VITA 66.x. The size and shape of the coupling end 210 and mating end 106 may vary.

In some embodiments, a shroud 208 is provided on top of the active device 204 to guide the active device 202 as it mechanically couples with the connector 104. In some embodiments, a thermal pad 212 is provided along a surface of the shroud 208, for interfacing with the connector 104. The thermal pad 212 may be used to eliminate air gaps between the active device 202 and the connector 104, in order to reduce thermal resistance. The thermal pad 212 may be made of any thermally conductive and electrically isolating material, such as a thermally conductive polymer.

In some embodiments, the connector 104 comprises one or more guiding pins 114 for aligning the connector 104 with the active device 202 for mechanical coupling. A slot may be provided in the shroud 208 for receiving the guiding pin 114. Guiding pins may also be provided on the active device 202 or on the shroud 208 for aligning the coupling end 210 of the active device 202 with the mating end 106 of the connector 104.

In some embodiments, a cable 112 extends outwardly from the back end of the connector 104. The cable 112 may be, for example, an optical fiber composed of multiple glass fibers in a laminated ribbon cable. Alternatively, the cable 112 may be an electrical cable for carrying current, composed of one or more wires running side by side or bundled. In some embodiments, the optical or electrical cable may be replaced by electrical contacts that mate to contacts on the backplane board itself, making the connector 104 also part of the backplane interconnect layer. The electrical contacts could also be optical contacts that allow light to pass from the active devices to a layer of optical waveguiding channels within the backplane.

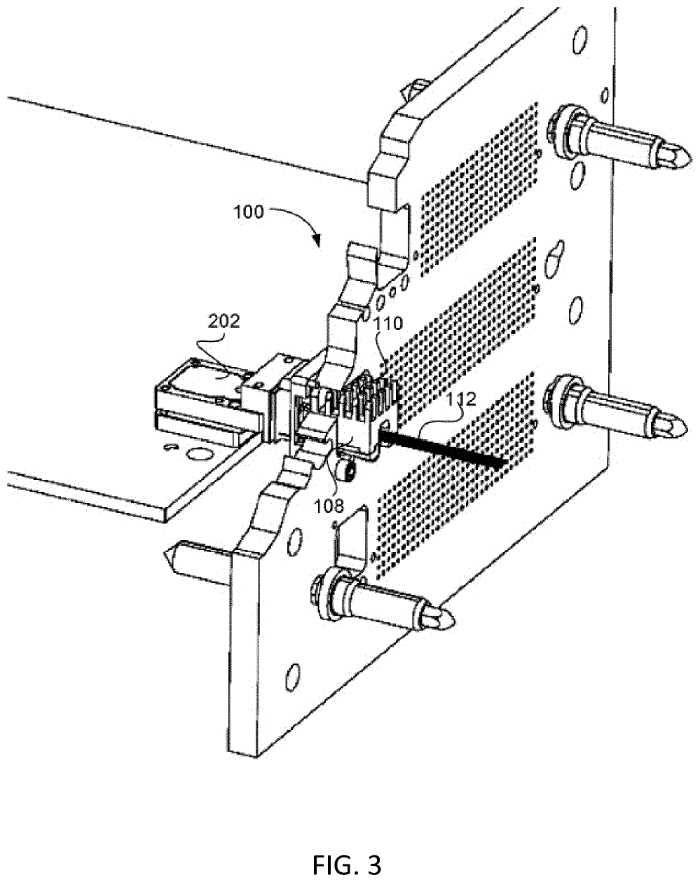

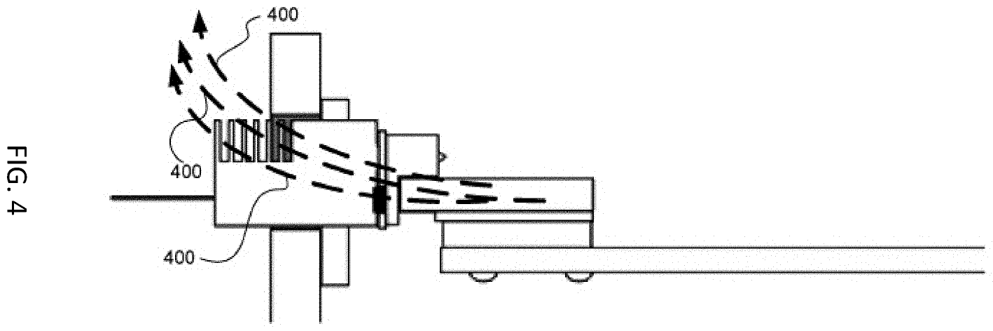

FIG. 3 is a perspective view of the active device 202 connected to the assembly 100. In this example, the cable 112 extends through the heatsink 108, underneath the fins 110. The fins 110 form a matrix of rows and columns. The presence of the heatsink 108 on the back side 102b of the board 102 creates a thermal path through the connector 104, from the mating end 106 to the back end. The thermal path draws heat generated by the active device 202 through the connector 104. The heat takes the path of least resistance and escapes through the fins 110 of the heatsink 108. This is illustrated in FIG. 4 with arrows 400 representing the thermal path as the heat is drawn through the connector 104 and dissipated behind the connector board 102 by the fins 110 of the heatsink 108. Excess heat is drawn out of the active module 202, thereby cooling the active module 202 and preventing a build-up of heat at the active module 202.

Heat flow can also be aided by the use of external fans on the backside of the backplane. This region typically has less obstructions for air-flow and therefore can be used to pull the heat from the inside of the assembly to the outside world more efficiently.

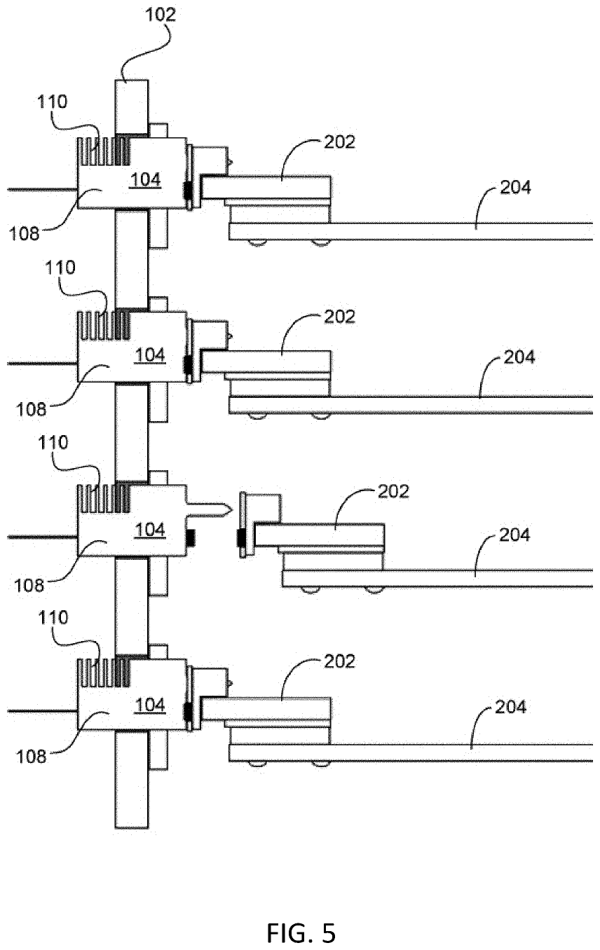

In some embodiments, a plurality of connectors 104 are mounted to the connector board 102, as illustrated in FIG. 5. Each connector 104 has its own heatsink 108 aligned therewith, either formed integrally with the connector 104 or separately therefrom. Each heatsink 108 comprises a plurality of fins 110. Each connector 104 is configured for mating with an active device 202 mounted to a device board 204.

The assembly 100 may be used in a method for dissipating heat generated by the active device 202 on the device board 204. The method comprises mating the active device 202 to the connector 104 mounted to the connector board 102. A thermal path is created through the connector 104 to the back side 102b of the connector board 102 with the heatsink 108 extending outwardly from the back side 102b of the connector board 102 and aligned with the connector 104. The heatsink 108 comprises fins 110 for dissipating the heat. When the active device 202 is operating, heat generated by the active device 202 is drawn through the thermal path and released at the fins 110 behind the connector board 102.

In some embodiments, the active device 202 is a transceiver, such as the LightCONEX™ optical transceiver by Reflex Photonics® and the connector 104 is compatible with the VMEbus International Trade Association (VITA) standards, such as VITA 66.4 and VITA 66.5. The mating end 106 of the connector 104 has a spring-loaded MT ferrule with coarse and fine mating alignment that is compatible with 12-lane OM3 or OM4 fiber ribbon cable. The active device 202 is MTh STD 883 compliant with a current mode logic (CML) data interface and land grid array (LGA) board mount. Possible applications for the assembly 100 connected with the active device 202 are VPX single board computers, digital Active Electronically Scanned Array (AESA) radars, phased array radars, high input/output density and high bandwidth communication links, and Interrupt Service Routine (ISR) embedded systems.

It should be understood that the connector 104 may be any type of optical connector, such as a Straight Tip (ST) connector, a Standard Connector (SC) connector, a Fiber Distributed Data Interface (FDDI) connector, a Multi-Fiber Push-On (MTP or MTO) connector, a Small Form Factor (SFF) connector, and an Infiniband™ connector. The coupling end 210 of the active device 202 may be complimentary to and compatible with any optical connector. The connector 104 may also be any type of electrical connector, such as the TE STRADA Whisper Backplane connector or the Amphenol (FCI) Metral Backplane connector. The coupling end 210 of the active device 202 may be complimentary to and compatible with any electrical connector.

The above description is meant to be exemplary only, and one skilled in the art will recognize that changes may be made to the embodiments described without departing from the scope of the invention disclosed. Still other modifications which fall within the scope of the present invention will be apparent to those skilled in the art, in light of a review of this disclosure.

Various aspects described herein may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments. Although particular embodiments have been shown and described, it will be apparent to those skilled in the art that changes and modifications may be made without departing from this invention in its broader aspects. The scope of the following claims should not be limited by the embodiments set forth in the examples, but should be given the broadest reasonable interpretation consistent with the description as a whole.

What is claimed is:

1. An assembly comprising:
a connector board having a front side and a back side;
a connector mounted to the connector board, the connector having a mating end extending outwardly from the front side of the connector board; and
a heatsink extending outwardly from the back side of the connector board and aligned with the connector, the heatsink comprising a plurality of fins extending parallel to the connector board for drawing heat through the connector from the front side to the back side of the connector board.

2. The assembly of claim 1, wherein the connector and the heatsink form an integral piece.

3. The assembly of claim 1, wherein the connector is embedded in the connector board and extends from the front side to the back side.

4. The assembly of claim 1, wherein the connector comprises at least one of an electrical cable, an optical cable, an electrical contact, or an optical contact.

5. The assembly of claim 1, wherein the connector is an optical connector.

6. The assembly of claim 5, wherein the optical connector comprises an optical fiber cable extending outwardly from the back side of the connector board.

7. The assembly of claim 6, wherein the optical fiber cable extends through the heatsink, underneath the plurality of fins.

8. The assembly of claim 1, wherein the plurality of fins comprise a matrix of at least two by two fins.

9. The assembly of claim 1, further comprising a plurality of connectors mounted to the connector board and a plurality of heatsinks aligned with the plurality of connectors.

10. The assembly of claim 1, further comprising:
a device board having a top surface and a bottom surface; and
an active device mounted to the top surface of the device board and mated with the mating end of the connector.

11. The assembly of claim 10, wherein the active device is an optical transceiver, and wherein the connector is an optical to electrical connector.

12. The assembly of claim 10, further comprising a thermal gap pad provided between the active device and the mating end of the connector.

13. A connector comprising:
a mating end configured for mating with an active device; and
a back end opposite the mating end, the back end comprising a heatsink aligned with the mating end and having a plurality of fins extending vertically for releasing heat drawn through the mating end.

14. The connector of claim 13, wherein the heatsink is formed integrally with the backend of the connector.

15. The connector of claim 13, further comprising at least one of an electrical cable, an optical cable, an electrical contact, or an optical contact.

16. The connector of claim 13, wherein the connector is an optical connector.

17. The connector of claim 16, further comprising an optical fiber cable extending outwardly from the back end.

18. The connector of claim 17, wherein the optical fiber cable extends through the heatsink, underneath the plurality of fins.

19. The connector of claim 13, wherein the plurality of fins comprise a matrix of at least two by two fins.

20. A method for dissipating heat generated by an active device on a device board, the method comprising:
mating the active device to a mating end of a connector mounted to a connector board, the mating end extending outwardly from a front side of the connector board;
creating a thermal path through the connector to a back side of the connector board with a heatsink extending outwardly from the back side of the connector board and aligned with the connector, the heatsink comprising a plurality of fins extending parallel to the connector board; and
drawing heat generated by the active device through the thermal path to release the heat at the back side of the connector board.
